(19) United States
(12) Patent Application Publication
(10) Pub. No.: US 2008/0248412 A1
(43) Pub. Date: Oct. 9, 2008

(54) SUPERVISORY ETCH CD CONTROL

(76) Inventors: John Douglas Stuber, Plano, TX (US); Hongyu Yue, Plano, TX (US)

Correspondence Address: TEXAS INSTRUMENTS INCORPORATED, P O BOX 655474, M/S 3999, DALLAS, TX, 75265, US

(21) Appl. No.: 11/697,840

(22) Filed: Apr. 9, 2007

(51) Int. Cl. H01L 21/66; G01B 11/02; G03F 7/20

(52) U.S. Cl. 430/30; 118/696

(57) ABSTRACT

Exemplary embodiments provide a controller system and method to control etch critical dimensions (CDs) during semiconductor manufacturing processes when the etch elements cannot be manipulated to control such end. The controller system includes a photo CD controller and an etch CD controller. The photo CD controller includes a first feedback loop that correlates a measured photo CD of a photo-processed semiconductor product back to the photo-process. The etch CD controller calculates a CD bias from the measured photo CD, a measured etch CD of a further etch-processed semiconductor product, and manufacturing targets for the photo CD and the etch CD. The CD bias is then fed back to the photo CD controller as a device-level CD-offset to adjust the target photo CD, which modifies the photo-process and generates the etch CD on the target etch CD. This automated etch CD control can be used for error corrections for product-to-product variations.

### FIELD OF THE INVENTION

This invention generally relates to semiconductor processing systems and, more particularly, to final critical dimension (CD) controls of the semiconductor processing systems.

### BACKGROUND OF THE INVENTION

Electrical devices, for example, transistors, capacitors, and the like, in integrated microelectronic circuits have become ever smaller in order to increase operational speed. The minimal dimensions of features of such devices are commonly called in the art, critical dimensions, or CDs. The CDs generally include the minimal widths of the features, such as lines, columns, openings, spaces between the lines, and the like. These features are generally fabricated by processes including a photo-process and an etching process. For example, the processes can include forming a patterned mask (e.g., photoresist mask) on a material layer by photolithographic techniques and then etching the material layer using the patterned mask as an etch mask by etch techniques.

The final critical dimension (i.e., etch CD) control is critical for semiconductor devices. One conventional method to control the etch CD is to change the etch recipes including etch time, gas ratio, and/or RF power of the etch process. In some processes such as dielectric trench etch, the etch time is manipulated in order to control the trench depth and cannot be further manipulated to control the CD. In other processes such as via etch, the etch time is determined dynamically by the detection of species from an etch stop layer and/or a decrease in the concentration of species from the dielectric layer. In this case, further etching causes deleterious effects on the features being etched, and therefore etch time cannot be manipulated to control the etch CD. Changes to etch chemistries can adjust the final etch critical dimensions. These changes, however, require re-qualification of the devices and are not allowed on a run-by-run basis.

Another conventional method to control the etch CD is to correlate the dimensional accuracy of the etch features with elements of the photo-process. For example, a feedback loop between the etch CD and the photo exposure can be implemented to control the etch CDs. However, this solution also has drawbacks and disadvantages. For example, the feedback loop can be an unstable control loop, due to a phase lag, that is, a large number of lots have already processed through photo-process but have not had their post-etch CD measured. As a result, this phase lag (e.g., in a discrete time controller) delivers unacceptable performance in etch CDs and does not provide a control methodology for the photo CDs.

Thus, there is a need to overcome these and other problems of the prior art and to provide a system and a method to control etch CDs.

### SUMMARY OF THE INVENTION

According to various embodiments, the present teachings include a semiconductor controller system. The semiconductor controller system can include a photo CD controller and an etch CD controller. The photo CD controller can include a first feedback loop that controls a measured photo CD (PCD) of a photo-processed semiconductor product by manipulating an element of the photo-process. The photo-processed semiconductor product is designed with a target photo CD (target PCD). The etch CD controller can include a second feedback loop that correlates a calculated CD bias back to the photo CD controller to adjust the target PCD determined by the calculated CD bias, such that a measured etch CD (ECD) of a further etch-processed semiconductor product is on a target etch CD (target ECD).

According to various embodiments, the present teachings also include a method of controlling semiconductor processes. In the method, a photo CD can be acquired after a semiconductor product has been processed by a photo-process. An etch CD can also be acquired after the semiconductor product has been further processed by an etch process. In this method, the etch CD should not be controlled by a typical etch control system using etch elements. An etch bias can then be determined from the acquired photo CD, the acquired etch CD, and a target photo CD as well as a target etch CD determined by a manufacturing execution system. The etch bias can then be added to the target photo CD to modify the photo-process to make the etch CD on the target etch CD.

According to various embodiments, the present teachings further include a system of processing semiconductor products. The system can include a first machine interface coupled to a photo-process tool for sending a control input parameter to the photo-process tool based on a target photo CD obtained from a manufacturing execution system. The system can also include a first metrology tool coupled to the photo-process tool and the first machine interface for acquiring data from a photo-processed semiconductor wafer and feeding back the acquired data to the first machine interface. The system can also include a second metrology tool coupled to an etch process tool, which can further process the photo-processed semiconductor wafer. In addition, the system can include a second machine interface coupled to and acquiring data from the second metrology tool, the first metrology tool, and the manufacturing execution system to calculate an etch CD bias. The second machine interface can further be coupled to the first machine interface to generate a feedback adjustment of the target photo CD to modify the control input parameter sent to the photo-process tool.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 depicts an exemplary etch CD controller system in accordance with the present teachings.

FIG. 2 depicts exemplary results of etch bias for various reticles used in a photo-process in accordance with the present teachings.

FIG. 3 depicts an exemplary method to control an etch CD in accordance with the present teachings.

FIG. 4 depicts exemplary results of etch CD control using the disclosed controller system and method in accordance with the present teachings.

### DESCRIPTION OF THE EMBODIMENTS

Reference will now be made in detail to the present embodiments (exemplary embodiments) of the invention, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” As used herein, the term “one or more of” with respect to a listing of items such as, for example, A and B, means A alone, B alone, or A and B. The term “at least one of” is used to mean one or more of the listed items can be selected.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

Exemplary embodiments provide a controller system and a method to control etch critical dimensions (etch CDs) during semiconductor manufacturing processes. The controller system can include a photo CD controller and an etch CD controller. The photo CD controller is a run-by-run controller including a first feedback loop that correlates a measured photo CD of a photo-processed semiconductor product back to the photo-process. The etch CD controller can calculate a CD bias (also referred to herein as “etch bias” or “etch CD bias”) based on the measured photo CD, a measured etch CD of a further etch-processed semiconductor product, as well as manufacturing targets for the photo CD and the etch CD. The CD bias can then be fed back to the photo CD controller and serve as a device-level CD-offset to adjust the target photo CD. The photo-process can then be modified such that the measured etch CD can be on the target etch CD. This automated etch CD control can be used for error correction for wafer-to-wafer variations for etch processes where etch time cannot or does not control the etch CD, in terms of quality and efficiency, in semiconductor manufacturing processes since wafer-to-wafer variations can result in an output of non-uniform semiconductor devices.

There can be many discrete processes that are involved in semiconductor manufacturing. For example, semiconductor products/devices including, but not limited to, a flash memory, a CPU (central processing unit), and a DSP (digital signal processor), can be fabricated by stepping through multiple manufacturing process tools including, for example, metal deposition process tools, photo-process tools, and/or etch process tools.

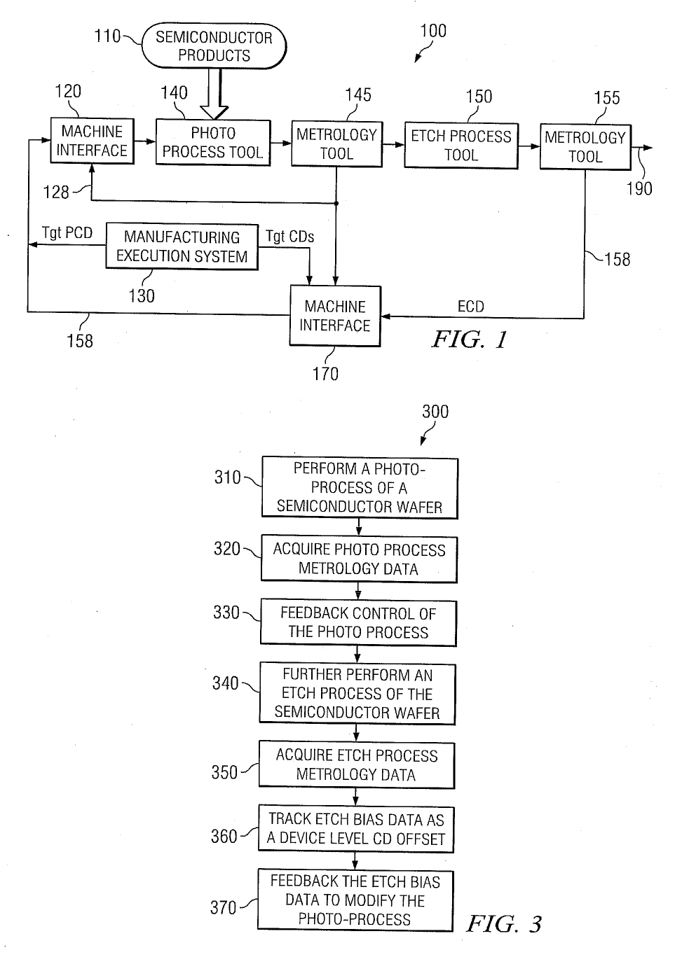

FIG. 1 depicts an exemplary etch CD controller system 100 for semiconductor manufacturing in accordance with the present teachings. It should be readily apparent to one of ordinary skill in the art that the controller system 100 depicted in FIG. 1 represents a generalized schematic illustration and that other elements/machines/process tools can be added or existing elements/machines/process tools can be removed or modified.

As shown in FIG. 1, the exemplary controller system 100 can include one or more semiconductor products/devices 110, a first machine interface 120, a manufacturing execution system (MES) 130, a photo-process tool 140, a first metrology tool 145, an etch process tool 150, a second metrology tool 155, and a second machine interface 170. The semiconductor products/devices 110, for example, semiconductor wafers, can be processed in a manufacturing environment including the photo-process tool 140 and thereafter the etch process tool 150.

Generally, a photo-process environment can include a reticle having a design dimension (e.g., target photo CD), and a stepper device with lens through which the exposure elements representing an exposure energy can be focused on a semiconductor material, such as a semiconductor product 110, coated with a photoresist. Thereafter, a printed wafer can be fabricated after the development of the photoresist providing a measured dimension (e.g., photo CD, also referred to in the art as “DICD” (i.e., developed inspection critical dimension)) with a deviation from the design target dimension (e.g., target photo CD) of the reticle.

The printed wafer can then be processed subsequently in a process tool, such as the etch process tool 150, which can result in a structured wafer having, for example, a measured etch critical dimension (e.g., etch CD, also referred to the art as “DICD” (i.e., final inspection critical dimension), final CD or final etch CD) from a design dimension (e.g., target etch CD) based on the applications of the semiconductor product 110. In various embodiments, the target photo CD (target PCD) and the target etch CD (target ECD) can be obtained from the MES 130.

In various embodiments, the controller system 100 can include two exemplary controllers including a photo CD controller and an etch CD controller. Each CD controller can include a feedback loop in order to automatically target the final ECD of the processed semiconductor product 110.

As shown in FIG. 1, the photo CD controller can include a first feedback loop 128 performed upon the first machine interface 120 to correlate a measured photo CD (PCD) back to the photo-process tool 140. The measured PCD of the semiconductor product 110 that has been processed from the photo-process tool 140, can be obtained using the first metrology tool 145.

Specifically, the first machine interface 120 can be connected to the photo-process tool 140 and define a process script and input control signals to the photo-process tool 140 by processing received data. For example, the first machine interface 120 can receive and process data of a target PCD obtained from the MES 130 and/or a measured PCD fed back from the metrology tool 145. In various embodiments, the first machine interface 120 can include a photo APC (Advanced Process Controller) frame work that includes a data process unit for a real-time data collection and analysis, for example, for a wafer-to-wafer control and/or module-level run-to-run control. In various embodiments, the first machine interface 120 can initiate a control script based upon a manufacturing model, which can be a software program installed in the first machine interface 120. The manufacturing model can automatically retrieve the data needed to execute a manufacturing process. In one embodiment, the first machine interface 120 can be located outside the photo-process tool 140. In an alternative embodiment, the machine interface can be located within the photo-process tool 140.

The photo-process tool 140 can be a standard photolithography process tool known to one of ordinary skill in the art. After processed by the photo-process tool 140, the semiconductor products 110 can be sent to the metrology tool 145.

The metrology tool 145 can be used for acquiring metrology data including measured PCDs of the photo-processed semiconductor products 110. The acquired (measured) data can then be fed back to the first machine interface 120, such as an APC frame work, to adjust the manufacturing model of the photo-process on a run-by-run basis. For example, to control critical dimensions within the photo-processes, the first feedback control loop 128 can be briefly executed as follows: running the photo-process tool 140 processed with exemplary focus and exposure settings on the semiconductor product 110; obtaining a measurement of photo critical dimension (PCD) by the metrology tool 145 for the resulting semiconductor product 110; and adjusting the process control parameters by the first machine interface 120 based on the received PCD measurements from the metrology tool 145 as compared to the target PCD from the MES 130.

Referring back to FIG. 1, the controller system 100 can further include the etch CD controller having a second feedback loop 158 performed upon the second machine interface 170. The second machine interface 170 can “supervise” the first feedback loop 128 of the photo CD controller by adjusting its target by the calculated CD bias.

The second feedback loop 158 of the etch CD controller can include the etch process tool 150, which can be a standard etch process tool known to one of ordinary skill in the art to process semiconductor products 110. Generally, the etch conditions/recipes, for example, an etch time, can be manipulated by a typical etch control system known in the art. In the case when the etch elements are controlled with an objective that is not the etch CD, for example, the typical etch control system can manipulate the etch time to control an objective, such as, a trench depth for gate etch of the transistors and with no further control of the etch CD, the disclosed etch CD controller system can be used. In various embodiments, the disclosed etch CD controller system can be used where the changes of etch time have deleterious effects on the features being etched and the etch time can not be manipulated to control the etch CD.

After the etch process, the etched semiconductor products 110 can be sent to the metrology tool 155 for further measurements. The metrology tool 155 can be used for acquiring metrology data including the etch CDs of the etch-processed semiconductor products 110. The measured ECD data can then be sent to the second machine interface 170, and also be processed and organized by the second machine interface 170.

The second machine interface 170 can be coupled to the metrology Tool 155, the MES 130, and the metrology tool 145 to receive and process the data therefrom to provide the calculated CD bias (i.e., etch bias or etch CD bias). In various embodiments, the second machine interface 170 can include an embedded software program for the data processing. The second machine interface 170 can further coupled to the first machine interface 120 of the feedback loop 128 of the photo CD controller.

The second machine interface 170 can be a similar device as to that of the first machine interface 120. For example, the second machine interface 170 can include an APC system. In various embodiments, the second machine interface 170 can include, for example, a low-pass filter (not shown), to reduce noise, and to determine and track the CD biases (i.e., etch bias) of the processed semiconductor products 110. The CD bias can be described herein using the following equation:

CD Bias=(PCD−ECD)−(target PCD−target ECD) (1)

Wherein the PCD and the ECD can be measured by the metrology tools 145 and 155, respectively, and the target PCD and the target ECD can be obtained from the MES 130. The PCD, the ECD, the target PCD and the target ECD can be collected, calculated, filtered, and tracked as the CD bias using the second machine interface 170, such as an APC frame work.

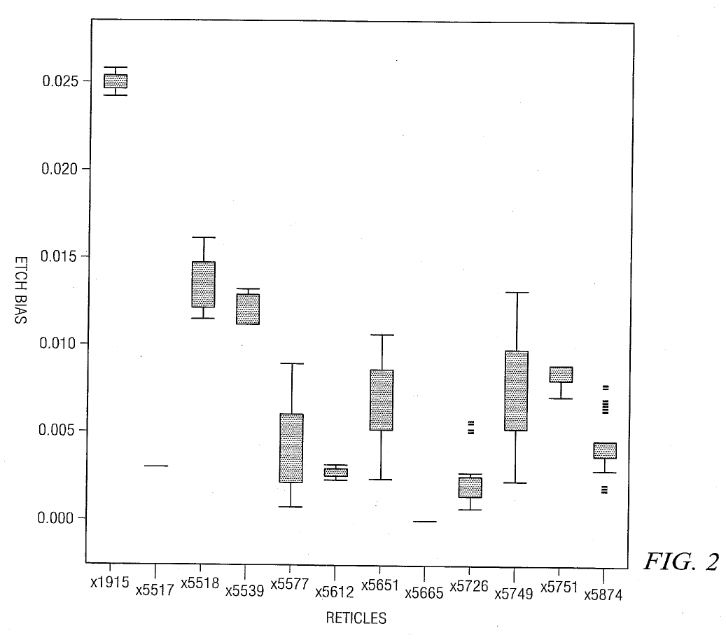

FIG. 2 depicts exemplary results of etch CD bias for various reticles used in a photo-process in accordance with the present teachings. The reticles in FIG. 2 have been run on the same resist at the same logpoint of the photo-process and have various different designs and applications. As shown, the resulting data for each etch CD bias can be significantly different from each reticle. That is, the etch CD bias can be a function of the reticle and the etch CD bias can vary for semiconductor devices having various different designs and applications. Such variances can then be eliminated by a subsequent process shown in FIG. 1.

Turing back to FIG. 1, the filtered and tracked etch bias can be sent back to and/or stored in the first machine interface 120. In some embodiments, the resulted CD bias data can be stored in the second machine interface 170 (e.g., an etch APC) and then sent to the first machine interface 120 (e.g., a photo APC). The filtered and tracked CD bias according to the equation (1) can be an etch feedback adjustment, that can be added to the target PCD and server as a device-level CD-offset for the controller system 100. That is, an adjusted target photo CD can be obtained as following:

Target adjusted PCD=Target PCD+CD Bias (2)

Because the target PCD can be adjusted by the CD bias as an offset as shown in equation (2), the first feedback loop 128 (see FIG. 1) of the photo CD controller can utilize etch feedback adjustment, i.e., the CD bias according to the equation (1), for a further example, each individual datum shown in FIG. 2, to make modifications for the manufacturing model, which can cause appropriate changes of the control input parameters for photo elements of the photo-process tool 140. In this manner, the existing measured PCD can be off target due to the adjustment of the target PCD.

In various embodiments, during a photo manufacturing process, such as a stepper process, the control input signals that are used to operate the photo-process tool 140 can include, but are not limited to, an exposure dose signal, a focus offset signal, a numerical aperture signal, a partial coherence signal, and a wafer stage height signal. The changes (modifications) of the control input parameters for photo elements can adjust the formation of the critical dimensions. For example, line-width adjustments of the critical dimensions for the semiconductor devices 110 can be performed using photo exposure dosage modifications, while line profile adjustments can be performed using exposure focus modifications.

As a result, these control input signals to control photo-elements of the photo-process tool 140 can be updated by adjusting the target PCD using the tracked CD bias (see equation (1) and FIG. 2) as a CD-offset (see equation (2)). Semiconductor device differences in ECDs can therefore be eliminated by automatically adjusting the target photo CD through the second machine interface 170 of the etch CD controller.

For example, the equations (1) and (2) can be combined as following:

Target adjusted PCD=PCD+target ECD−Etch CD (3)

When the target PCD has been adjusted, the first machine interface 120 of the photo CD controller can drive the actual PCD (i.e., the measured photo critical dimension) to the adjusted target PCD by manipulating exposure conditions of the photo-process. In this case, as referring to the equation (3), the actual ECD can be driven to the target ECD, that is, the actual ECD can be on the target ECD and the etch CD delta can be driven to 0.

It is noted that the actual ECD can be controlled by the automatically-adjusted target PCD with no need to change etch conditions /recipes, with no need to track exactly with target changes, and with no need to synchronize changes for the photo and the etch targets. In various embodiments, the PCDs can be retargeted manually depending on, for example, the designs and applications of the semiconductor devices 110. In various embodiments, the ECDs can be retargeted based on, for example, the manufacturing process, the reliability and/or the yield of the fabricated semiconductor devices.

Referring back to FIG. 1, a line 190 can be included in the controller system 100 for a continued step of, for example, a data process or a fabrication process. For example, standard statistical process control (SPC) such as a photo SPC and/or an etch SPC can be used in a form of control charts. The SPC can track all delta CDs, including the photo delta CD and/or etch delta CD, using the same set of control limits. Alternatively, separated control charts with independent control limits can be used for the exemplary photo SPC and/or the etch SPC.

FIG. 3 depicts an exemplary method 300 to control an etch CD in accordance with the present teachings. As shown, at 310, a manufacturing run of semiconductor wafers, for example, a photolithography process can be performed. At 320, metrology data such as photo CDs of the photo-processed semiconductor wafers can be acquired by an exemplary metrology tool. At 330, the acquired metrology data from 320 can then be fed back to control the photo-process, for example, to control exposure dose and/or focus offset through a machine interface such as an APC. At 340, an etch process can be subsequently performed on the semiconductor wafers with desired etch conditions including etch time and/or etch chemistries. The etch process can include, for example, a wet etching or a dry etching. At 350, metrology data such as etch CDs of the etch-processed semiconductor wafers can be acquired by a metrology tool, for example. At 360, etch biases (i.e., CD biases or etch CD biases) can be calculated and filtered, upon a machine interface such as an APC, based on the measured photo CDs at 320, the measured etch CDs at 350, as well as target photo CDs and target etch CDs obtained from an manufacturing execution system based on the designs and applications of the semiconductor devices. At 370, the calculated etch biases can be added to adjust the target photo CDs as device-level CD-offsets. The adjusted target photo CDs can be used to modify the photo-process of the photo CD controller and thus to control the final etch CD.

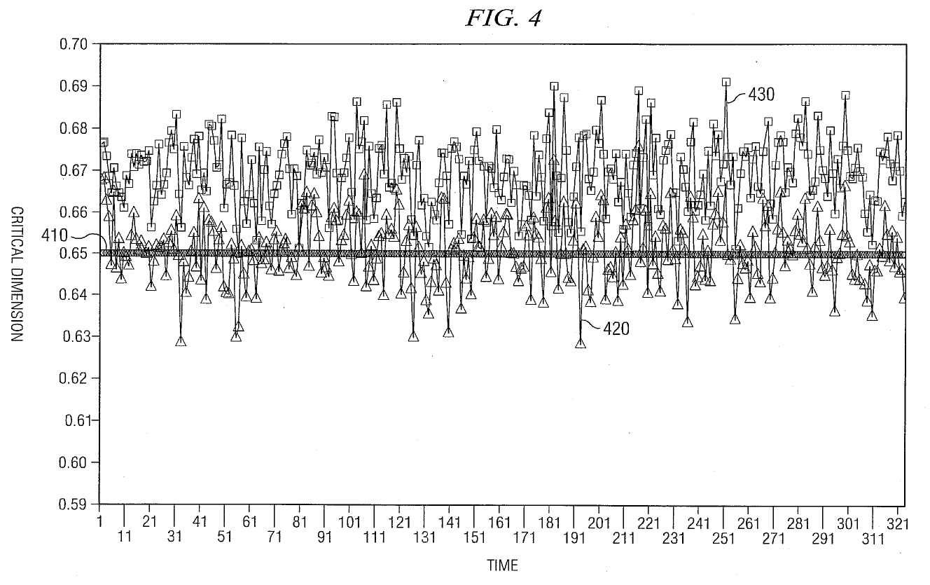

FIG. 4 depicts exemplary results of the etch CD controlled by the disclosed controller system and method as shown in FIG. 1 and FIG. 3 in accordance with the present teachings. Particularly, FIG. 4 describes a relationship between etch CDs of each wafer of a semiconductor wafer lot over time. Three exemplary comparable plots 410, 420, and 430 are shown for target etch CDs, controlled final etch CDs using the disclosed controller system and method, and non-controlled final etch CDs, respectively.

Specifically, the plot 410 depicts desired target etch CDs having a constant dimension of about 0.65 microns for such as a line width. The plot 420 depicts the controlled final etch CDs can be vibrated around the desired target etch CDs, i.e., each etch CD can be controlled to be on etch target etch CD. This is because the each etch CD of the plot 420 can be controlled by adjusting its target photo CD with an etch bias offset for the photo-process of the photo CD controller. The etch bias can be determined by both the photo CD controller and the etch CD controller of the controller system as described in FIG. 1. For comparison, the plot 430 depicts the non-controlled final etch CDs with no use of the disclosed controller system and the method having a deviation away from their target etch CDs.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor controller system comprising:
a photo CD controller comprising a first feedback loop that controls a measured photo CD (PCD) of a photo-processed semiconductor product by manipulating an element of the photo-process, wherein the photo-processed semiconductor product is designed with a target photo CD (target PCD); and
an etch CD controller comprising a second feedback loop that correlates a calculated CD bias back to the photo CD controller to adjust the target PCD determined by the calculated CD bias, such that a measured etch CD (ECD) of a further etch-processed semiconductor product is on a target etch CD (target ECD).

2. The system of claim 1, wherein the calculated CD bias is determined by,
CD bias=(PCD−ECD)−(target PCD‘target ECD), wherein
PCD is the measured photo CD of the photo-processed semiconductor product PCD, ECD is the measured etch CD of the further etch-processed. semiconductor product, and the target PCD and the target ECD are determined by manufacturing designs and applications.

3. The system of claim 1, wherein the adjusted target PCD is determined by adding the calculated CD bias to the target PCD, wherein the calculated CD bias is a device-level CD-offset.

4. The system of claim 1, wherein one or more of the measured PCD and the measured ECD are obtained using a metrology tool.

5. The system of claim 1, wherein the photo CD controller comprises a first machine interface to feedback the measured PCD to the photo-process.

6. The system of claim 5, wherein the etch CD controller comprises a second machine interface connected to the first machine interface of the photo CD controller, wherein each of the first machine interface and the second machine interface comprises an Advanced Process Controller (APC).

7. The system of claim 1, wherein the etch CD controller comprises a second machine interface to calculate and feedback the CD bias to the photo CD controller, wherein the second machine interface is connected to receive and process data of the measured PCD, the target PCD, the measured ECD and the target ECD.

8. The system of claim 1, wherein the etch CD controller comprises a low-pass filter to filter and track the calculated CD bias.

9. The system of claim 1, wherein the element of the photo-process comprises one or more of an exposure dosage, a focus offset, a numerical aperture, a partial coherence, and a wafer stage height.

10. The system of claim 1, wherein the semiconductor product comprises one or more devices selected from the group consisting of a flash memory, a central processing unit (CPU), and a digital signal processor (DSP).

11. A method of controlling semiconductor processes comprising:
acquiring a photo CD of a semiconductor product processed by a photo-process, wherein the semiconductor product is further processed by an etch process;
acquiring an etch CD of the further etch-processed semiconductor product, wherein no etch element controls the etch CD by a typical etch control system;
determining an etch bias from the acquired photo CD, the acquired etch CD, a target photo CD and a target etch CD, wherein the target photo CD and the target etch CD are determined by a manufacturing execution system;
adjusting target photo CD by adding the etch bias to the target photo CD from the manufacturing execution system; and
targeting etch CD by modifying the photo-process in response to the adjusted target photo CD.

12. The method of claim 11, further comprising:
performing a feedback modification process to the photo-process in response to the acquired photo CD upon a photo Advanced Process Controller (APC).

13. The method of claim 11, wherein no etch element controls the etch CD by the typical etch control system comprises, an etch time is manipulated by the typical etch control system with an objective of a trench depth, and changes in the etch time have deleterious effects on a feature being etched.

14. The method of claim 11, further comprising an etch Advanced Process Controller (APC) to determine the etch bias, adjust target photo CD, and feedback to the photo-process.

15. The method of claim 11, wherein the etch bias is determined by,
Etch bias=(Photo CD−Etch CD)−(target Photo CD−target Etch CD),
wherein
the Photo CD is acquired from the photo-processed semiconductor product, the Etch CD is acquired from the further etch-processed semiconductor product, and the target Photo CD and the target Etch CD are determined by the manufacturing execution system.

16. The method of claim 11, wherein modifying the photo-process comprises modifying exposure dose in a photolithography process.

17. A system of processing semiconductor products comprising:
a first machine interface coupled to a photo-process tool for sending a control input parameter to the photo-process tool based on a target photo CD from a manufacturing execution system;
a first metrology tool coupled to the photo-process tool and the first machine interface for acquiring data from a photo-processed semiconductor wafer and feeding back the acquired data to the first machine interface;
a second metrology tool coupled to an etch process tool, wherein the etch process tool further processes the photo-processed semiconductor wafer; and
a second machine interface coupled to and acquiring data from the second metrology tool, the first metrology tool, and the manufacturing execution system to calculate an etch CD bias, wherein the second machine interface is further coupled to the first machine interface to generate a feedback adjustment of the target photo CD to modify the control input parameter sent to the photo-process tool.

18. The system of claim 17, wherein each of the first machine interface and the second machine interface comprises an Advanced Process Controller (APC).

19. The system of claim 17, wherein the control input parameter comprises one or more of an exposure dose signal, a focus offset signal, a numerical aperture signal, a partial coherence signal, and a wafer stage height signal.

20. The system of claim 17, wherein the first metrology tool acquires data of a photo CD and sends the acquired photo CD data to the first machine interface and the second machine interface.

21. The system of claim 17, wherein the second machine interface calculates the etch CD bias, wherein
Etch CD bias=(Photo CD−Etch CD)−(target Photo CD−target Etch CD)
and wherein
the Photo CD is acquired from the first metrology tool, the Etch CD is acquired from the second metrology tool, and the target Photo CD and the target Etch CD are obtained from the manufacturing execution system.

22. The system of claim 17, wherein the second machine interface comprises a low-pass filter to filter and track the calculated etch CD bias

23. The system of claim 17, wherein the feedback adjustment of the target photo CD comprises an addition of the etch CD bias to the target photo CD.
